(19) United States
(12) Patent Application Publication
(10) Pub. No.: US 2006/0113066 A1
(43) Pub. Date: Jun. 1, 2006

(54) Heat exchanger configuration for pumped liquid cooling computer systems

(75) Inventors: Rajiv K. Mongia, Portland, OR (US); Himanshu Pokharna, San Jose, CA (US); Eric Distefano, Livermore, CA (US)

Correspondence Address: INTEL CORPORATION, P.O. BOX 5326, SANTA CLARA, CA, 95056-5326, US

(73) Assignee: Intel Corporation

(21) Appl. No.: 11/001,896

(22) Filed: Dec. 1, 2004

(51) Int. Cl. H05K 7/20

(52) U.S. Cl. 165/104.33; 165/80.4; 361/699

(57) ABSTRACT

A cooling system using counter-flow air and fins with thermal isolation sections is disclosed. The cooling system includes a pump and a liquid coolant. Counter-flow air is applied in a direction generally opposite to a direction of the liquid coolant. The thermally isolation fins help reducing conduction of heat.

### COPYRIGHT NOTICE

Contained herein is material that is subject to copyright protection. The copyright owner has no objection to the facsimile reproduction of the patent disclosure by any person as it appears in the Patent and Trademark Office patent files or records, but otherwise reserves all rights to the copyright whatsoever.

### FIELD OF THE INVENTION

The present invention generally relates to cooling systems. More specifically, the present invention relates to cooling computer systems using pumped liquid cooling.

### BACKGROUND

As computer systems become faster, electronic components in the computer systems generate more heat requiring more efficient cooling techniques. One cooling technique is liquid cooling. Liquid cooling may be able to accommodate faster and denser electronic components because of their higher amount of power dissipation and heat generation. One category of liquid cooling is indirect liquid cooling. In indirect liquid cooling, the electronic component does not come in direct contact with the coolant. Heat generated by the electronic component may be transferred to the coolant. The heat may then be directed toward a heat exchanger for cooling.

### BRIEF DESCRIPTION OF THE DRAWINGS

Embodiments of the present invention are illustrated by way of example, and not by way of limitation, in the figures of the accompanying drawings and in which like reference numerals refer to similar elements and in which:

FIGS. 1A and 1B are block diagrams illustrating an example of a liquid cooling system using a liquid coolant, in accordance with one embodiment.

FIG. 2A is block diagrams illustrating an example of a cooling system with a multi-pass heat exchanger and cross-flow air, in accordance with one embodiment.

FIG. 2B is a diagram illustrating one example of a fin that may be used with a multi-pass heat exchanger, in accordance with one embodiment.

FIG. 3A is a diagram illustrating one example of a liquid cooling system using a heat exchanger with counter-flow air, in accordance with one embodiment.

FIG. 3B illustrates one example of a flow distribution plate that includes multiple parallel flow distribution paths, in accordance with one embodiment.

FIG. 3C illustrates a side view example of a fin attached to a flow distribution path in a heat exchanger with counter-flow air, in accordance with one embodiment.

FIG. 4A is a diagram illustrating an example of a multi-phase heat exchanger with four passes through the associated fins, in accordance with one embodiment.

FIG. 4B is a diagram illustrating an example of a fin used with a multi-pass heat exchanger, in accordance with one embodiment.

FIG. 4C is a diagram illustrating an example of a thermally isolated fin that may be used with a multi-pass heat exchanger, in accordance with one embodiment.

FIGS. 4D and 4E are diagrams illustrating an example of a thermally isolated fin that may be used with a heat exchanger and counter-flow air, in accordance with one embodiment.

FIG. 5 is a flow diagram illustrating one example of a process that may be used to cool an electronic component using counter-flow air and/or one or more thermally isolated fins, in accordance with one embodiment.

### DETAILED DESCRIPTION

For one embodiment, an apparatus and a method for cooling electronic components in a computer system using a liquid cooling system is disclosed. The liquid cooling system may include a pump, a heat exchanger, and a liquid coolant. The liquid cooling system may enable transferring of heat generated by an electronic component in the computer system to a heat exchanger with counter-flow air.

In the following description, for purposes of explanation, numerous specific details are set forth in order to provide a thorough understanding of the present invention. It will be evident, however, to one skilled in the art that the present invention may be practiced without these specific details. In other instances, well-known structures, processes and devices are shown in block diagram form or are referred to in a summary manner in order to provide an explanation without undue detail.

As used herein, the term “when” may be used to indicate the temporal nature of an event. For example, the phrase “event ‘A’ occurs when event ‘B’ occurs” is to be interpreted to mean that event A may occur before, during, or after the occurrence of event B, but is nonetheless associated with the occurrence of event B. For example, event A occurs when event B occurs if event A occurs in response to the occurrence of event B or in response to a signal indicating that event B has occurred, is occurring, or will occur.

Reference in the specification to “one embodiment” or “an embodiment” of the present invention means that a particular feature, structure or characteristic described in connection with the embodiment is included in at least one embodiment of the present invention. Thus, the appearances of the phrase “for one embodiment” or “in accordance with one embodiment” appearing in various places throughout the specification are not necessarily all referring to the same embodiment.

Pumped Liquid Cooling System

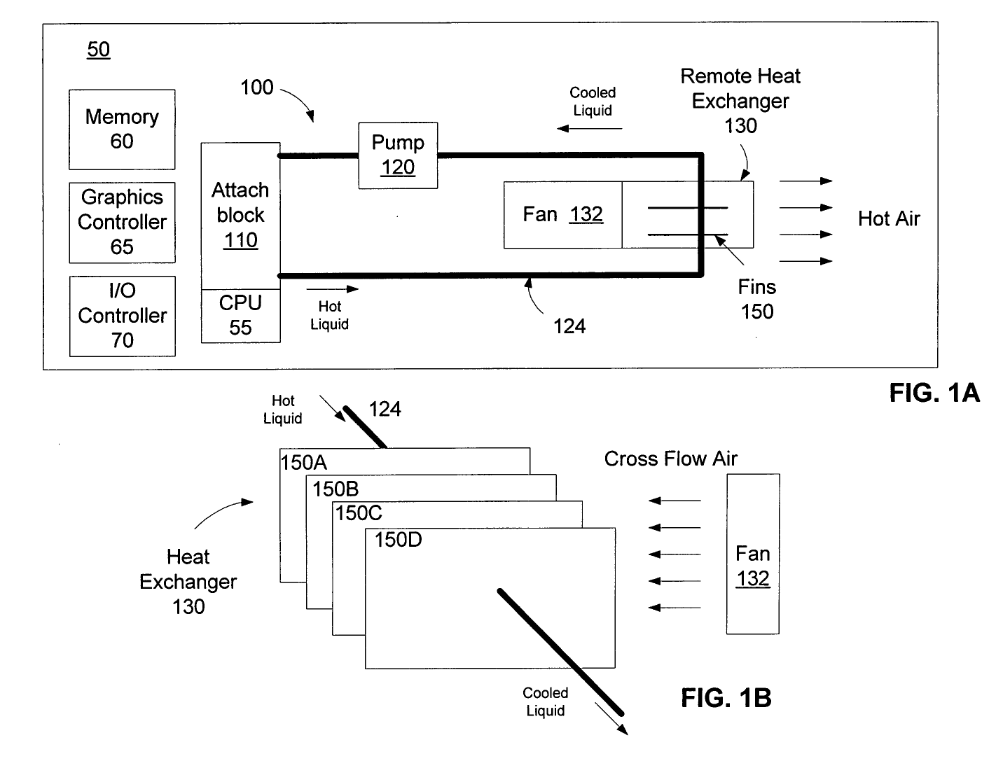

FIG. 1A is a block diagram illustrating an example of a computer system having a liquid cooling system that uses liquid coolant, in accordance with one embodiment. Computer system 50 may include processor 55, memory 60, graphics controller 65, Input/Output (I/O) controller 70, and other components (not shown). The computer system 50 may also include liquid cooling system 100 which may include attach block 110 coupled to an electronic component such as, for example, the processor 55. In this example, the liquid cooling system 100 may include a tube 124 coupled to the attach block 110. The liquid coolant may be water, liquid metal, etc.

The tube 124 may be implemented using a rigid or flexible material. The rigidity and flexibility properties of the tube material may enable the tube 124 to be easily routed around other electronic components inside the computer system. This may also enable the liquid cooling system 100 to be implemented with remote heat exchanger (RHE) 130 placed at a distance from the attach block 110. For one embodiment, the tube material may be thermally conductive. For example, the tube 124 may be metal tubes, although other types of materials that allow heated liquid coolant to flow through may also be used, depending on the type of liquid coolant or cooling application. The RHE 130 may be coupled to fan 132 which generates air flow. The fan 132 may be mounted directly to the RHE 130, or it may be positioned next to the RHE 130.

To enhance the flow of the liquid coolant between the attach block 110 and the RHE 130, pump 120 may be used. The pump 120 may be a mechanical pump or an electromagnetic pump. For example, the pump 120 may be a conduction pump, induction pump, centrifugal pump, regenerative turbo pump, magnetohydrodynamic (MHD) pump, piezo pump, etc. The pump 120 may be connected to the tube 124.

For one embodiment, the liquid cooling system 100 may be a closed-loop system. In the closed-loop system, the liquid coolant circulates between the attach block 110 and the RHE 130 or between one area of the computer system and another area of the computer system. Referring to the example illustrated in FIG. 1A, the tube 124 may be part of the closed loop that transports hot liquid coolant away from the attach block 110 and cooled liquid coolant away from the RHE 130.

Heat Exchanger Fins and Cross-Flow Air

FIG. 1B is a block diagram illustrating an example of fins in a heat exchanger, in accordance with one embodiment. The RHE 130 may include multiple fins 150A-150D. At the RHE 130, the heat may be extracted from the hot liquid coolant by the fins 150A-150D. The heat may then be rejected from the fins 150A-150D into the ambient air through force convection. The air flow generated by the fan 132 helps rejecting the heat from the fins 150. The air flow is referred to as a “cross flow” because it flows orthogonal to the flow of the liquid coolant. It may be noted that the RHE 130 as illustrated in FIGS. 1A and 1B is referred to as a single pass heat exchanger because there is only one pass of the tube 124 through the fins 150A-150D.

Using cross-flow air may be convenient, but it may not be efficient from a heat transfer perspective. For example, referring to FIG. 1B, the liquid coolant is hot when it enters a region between the fins 150A and 150B, and it may be cooler when it enters a region between the fins 150C and 150D. As a result, the cooling efficiency of the cool air from the fan 132 may be higher when the liquid coolant is passing through the fins 150A and 150B, and it may be lower when the liquid coolant is passing through the fins 150C and 150D.

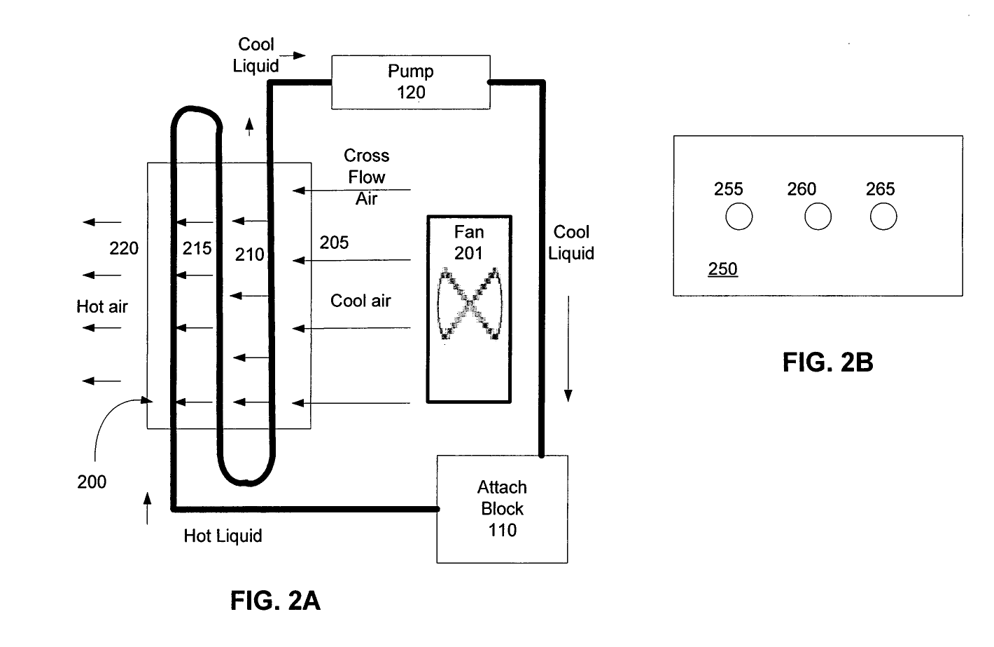

FIG. 2A is a block diagrams illustrating an example of a multi-pass heat exchanger with cross-flow air, in accordance with one embodiment. Heat exchanger 200 may be a RHE and may accommodate three passes of the cooling loop. In this example, the air flow provided by the fan 201 may pick up temperature as it flows across the loop of the multi-pass heat exchanger 200. The air temperature may be coolest in region 205. It may be hotter in region 210, and may become hottest in region 220. The liquid coolant may be hottest entering the heat exchanger 200 (between the regions 215 and 220) and may be coolest exiting the heat exchanger 200 (between the regions 210 and 205). Thus, in between the regions 205 and 210, the air temperature may be coolest while the liquid coolant may also be coolest, and in between the regions 215 and 220, the air temperature may be hottest while the liquid coolant may also be hottest.

FIG. 2B illustrates one example of a fin that may be used in a multi-pass heat exchanger, in accordance with one embodiment. In this example, fin 250 may accommodate hot liquid coolant in a first pass (or entry pass) through opening 255, cooler liquid coolant in a second pass through opening 260, and even cooler liquid coolant in a third pass (or exit pass) through opening 265.

In a multi-pass heat exchanger such as, for example, the heat exchanger 200, the conduction through the fin may negate much of the cooling benefit of the heat exchanger. For example, referring to FIG. 2B, because of heat conduction, the heat absorbed by the fin 250 from the liquid coolant in the first pass may affect the efficiency of the fin 250 when the liquid coolant flows through the fin 250 in the second pass and in the third pass.

Heat Exchanger with Counter-Flow Air

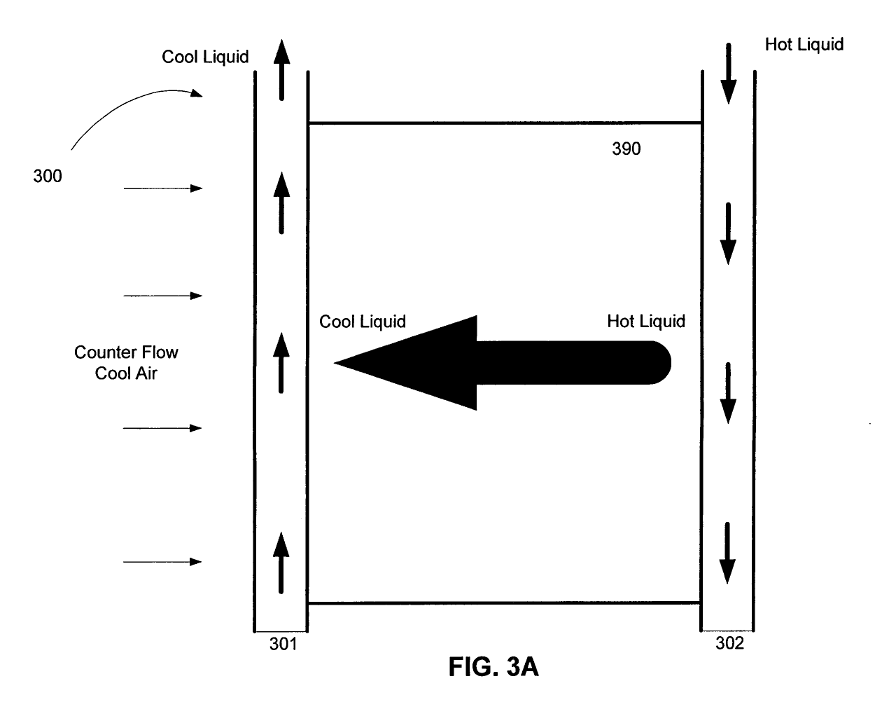

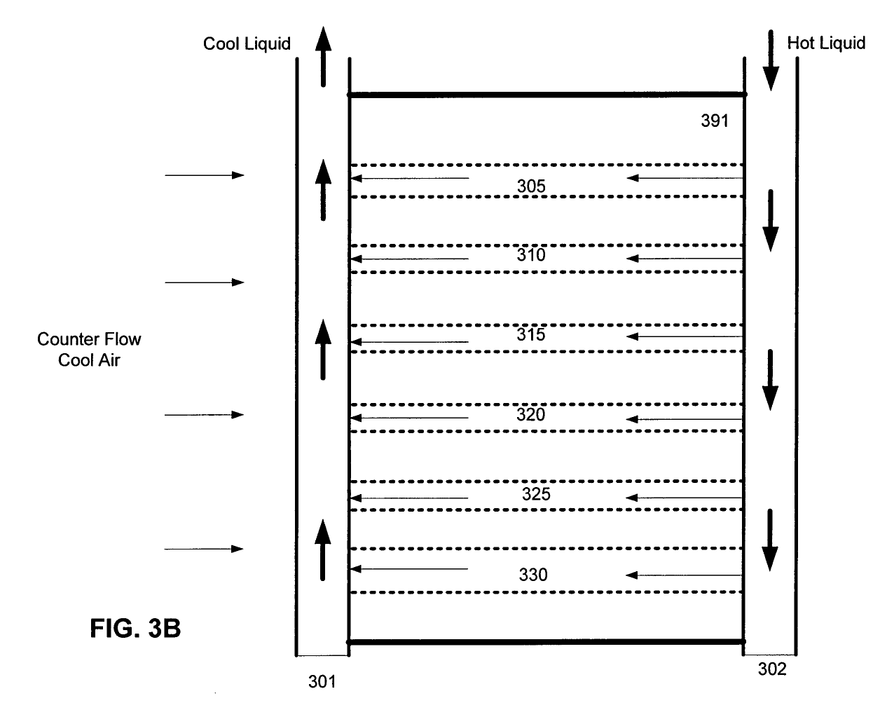

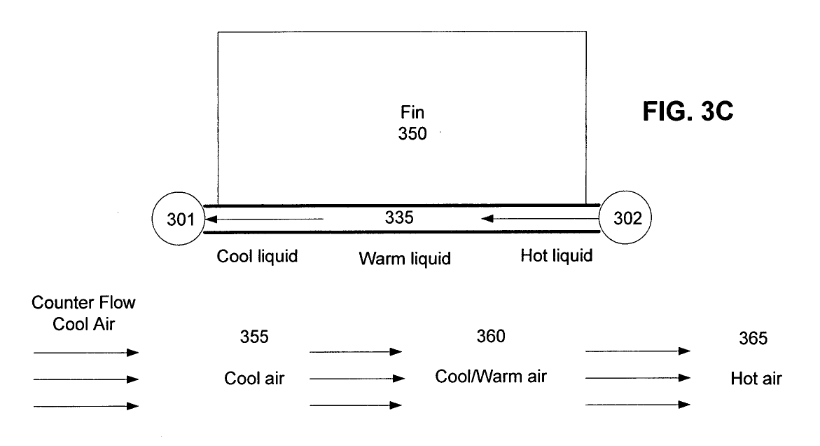

FIG. 3A illustrates one example of a heat exchanger with counter-flow air, in accordance with one embodiment. Heat exchanger 300 may include an entry tube 302 and an exit tube 301. The heat exchanger 300 may be a variation of a two-pass heat exchanger although the entry tube 302 may not be directly connected to the exit tube 301. The heat exchanger 300 may include a flow distribution plate 390 connecting the entry tube or inlet 302 to the exit tube or outlet 301. For one embodiment, the flow distribution plate 390 may include one or more flow distribution paths that may allow the liquid coolant to flow from the entry tube 302 to the exit tube 301 in a direction (as shown by the bold arrow) generally opposite to the direction of the air flow provided by a fan (not shown). This air flow may be referred to herein as a counter-flow air. It may be noted that as the liquid coolant flows along the flow distribution plate 390 toward the exit tube 301, the temperature of the liquid coolant may become cooler.

For one embodiment, the one or more flow distribution paths may be identical. For another embodiment, the one or more flow distribution paths may have different lengths, sizes, and/or shapes. For example, it may be possible to have two uniform flow distribution paths, each transporting approximately a similar volume of liquid coolant per unit of time. Alternatively, it may be possible to have two non-uniform flow distribution paths.

FIG. 3B illustrates one example of a flow distribution plate 391 that includes multiple parallel flow distribution paths 305-330. It may be noted that in this example the flow distribution paths 305-325 may be uniform with one another, while the flow distribution path 330 may be different from the other flow distribution paths.

FIG. 3C illustrates a side view example of a fin attached to a section of a flow distribution plate, in accordance with one embodiment. Fin 350 may be part of the heat exchanger 300 illustrated in FIG. 3A and may be attached to a flow distribution plate having a flow distribution path 335. The fin 350 may help providing additional heat transfer area to the heat exchanger 300. There may be multiple fins arranged along the direction from the entry tube 302 to the exit tube 301. This arrangement may enable the counter-flow air to flow across the heat exchanger 300 along the direction of the fins including the fin 350 and may enhance the efficiency of the heat exchanger 300.

As the hot liquid coolant enters the flow distribution path 335 from the entry tube 302, heat from the liquid coolant may begin to be transferred to the fin 350. The liquid coolant may become less hot (or warm) as it is transported through the flow distribution path 335, and may become cool when it reaches the end of the flow distribution path 335 before entering the exit tube 301. FIG. 3C also illustrates an example of the counter-flow air flowing across the heat exchanger 300 from the direction of the exit tube 301 to the entry tube 302. The counter-flow air is shown separately in this example for ease of illustration only but may be viewed as flowing across the flow distribution plate associated with the flow distribution path 335. As illustrated, the air temperature is cool in approximately region 355. It may be noted that, in approximately the region 355, the liquid coolant is cooler than when it enters the flow distribution path 335. The air temperature may still be cool or somewhat warmer in approximately region 360. This may be because the liquid coolant is warmer in this region and may cause an increase in the air temperature. The air temperature may be at its highest in approximately region 365. This may be because the liquid coolant temperature may also be at its highest when it encounters the air flow from the region 360. It may be noted that the counter-flow air illustrated in this example may be more efficient than a cross-flow air because the air temperature may remain relatively cool in a region (e.g., region 355) where the liquid coolant is cool.

Fin with Thermal Isolation Sections

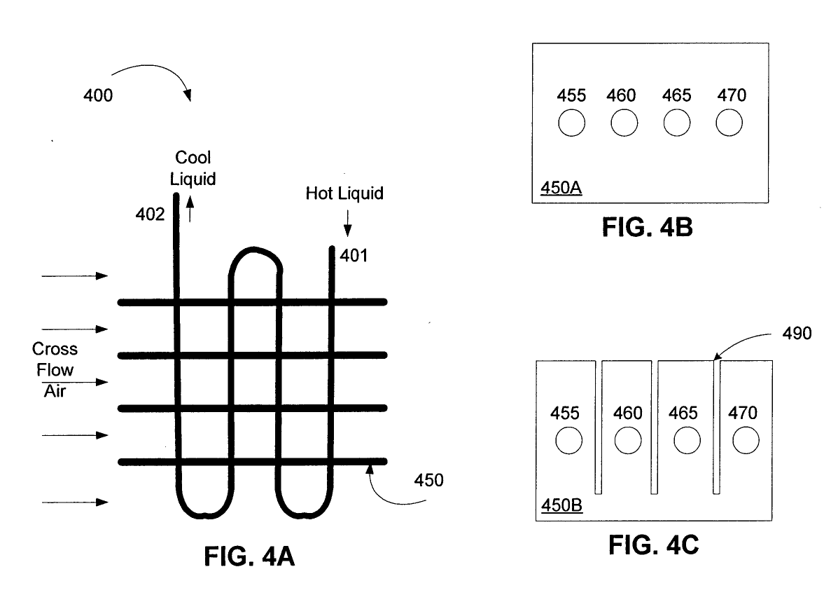

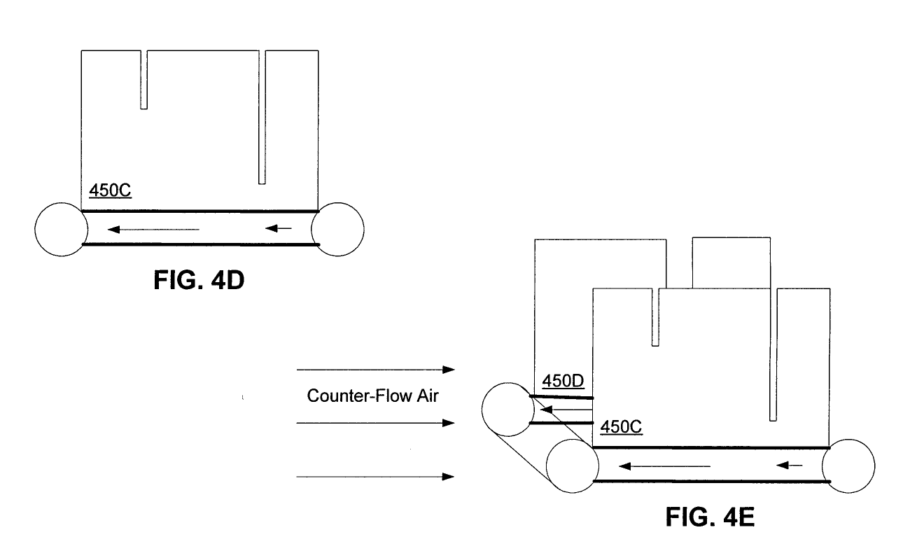

FIG. 4A is a diagram illustrating an example of a multi-phase heat exchanger with four passes through the associated fins, in accordance with one embodiment. Heat exchanger 400 receives hot liquid coolant at entry point 401 and discharges cool liquid coolant at exit point 402. The heat exchanger 400 may include multiple fins including fin 450.

FIG. 4B is a diagram illustrating an example of the fin 450 (referred to as fin 450A). The fin 450A includes four openings 455-470 to support the four passes of the liquid coolant through the heat exchanger 400. As described earlier, because of conduction, the design of the fin 450A may not be efficient in transferring heat from the liquid coolant.

For one embodiment, the fin 450A may be partially separated to create thermal isolation. For another embodiment, a section of the fin 450A that is associated with one pass of the heat exchanger 400 may be thermally isolated from another section of the fin 450A that is associated with an adjacent pass of the heat exchanger 400. For one embodiment, thermal isolation may be caused by partially separating the fin 450A into two or more sections. FIG. 4C illustrates one example of thermally isolating a fin, in accordance with one embodiment. For one embodiment, a cut 490 may be introduced into the fin 450B to thermally isolate the section of the fin 450B that is associated with the opening 465 and the section of the fin 450B that is associated with the opening 470. The cut may extend below the opening 465 or 470. Other additional cuts may also be introduced to the fin 450B. For another embodiment, sections of the fin 450B may be thermally isolated by perforation. For another embodiment, the sections of the fin 450B may be thermally isolated by using thinner sections within the fin. Other techniques of thermal isolation may also be used.

Referring to FIG. 4C, the thermal isolation cuts may be the same or uniform. For one embodiment, the thermal isolation cuts may be non-uniform, as long as they provide some levels of isolation, as illustrated in fin 450C in FIG. 4D. The fin with thermal isolation sections may be used in a heat exchanger having the cross-flow air, or it may be used in a heat exchanger having the counter-flow air, illustrated as fins 450C and 450D in FIG. 4E. Having thermal isolation in a fin may help enhance the efficiency of the heat exchanger 400 or heat exchanger 300. This may be particular useful in a notebook or a portable computer system where space may be limited.

Process

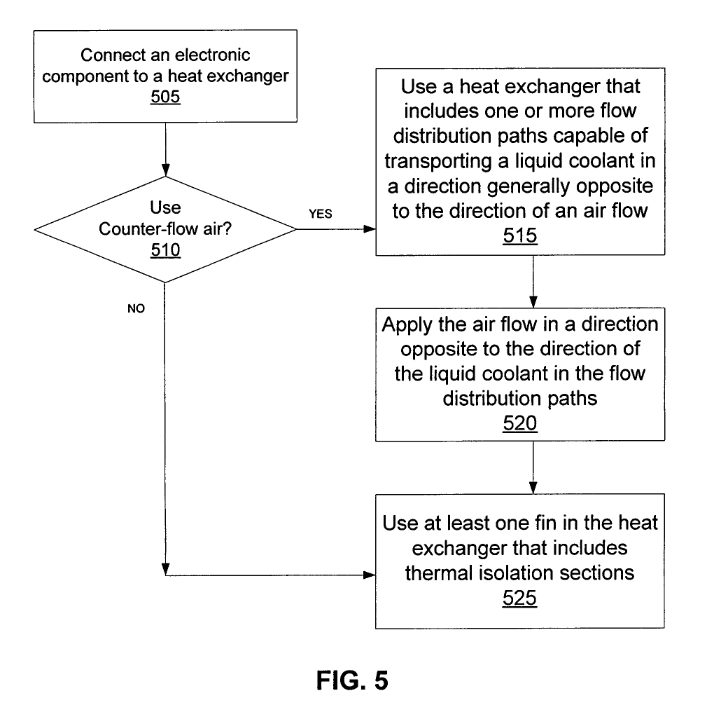

FIG. 5 is a flow diagram illustrating one example of a process that may be used to cool an electronic component using counter-flow air and/or one or more fins with thermal isolation, in accordance with one embodiment. At block 505, an electronic component is connected to a heat exchanger. At block 510, a test is made to determine if the counter-flow air is to be used. If yes, the heat exchanger is to include a flow distribution plate. The flow distribution plate may have multiple flow distribution paths capable of transporting a liquid coolant in a direction that is generally opposite to the direction of the air flow, as shown in block 515. At block 520, the counter-flow air is applied to the heat exchanger. The counter-flow air may be applied approximately opposite to the direction of the liquid coolant in the flow distribution paths. At block 525, to enhance the efficiency of the heat exchanger, one or more fins with thermal isolation sections may be used. From block 510, if the heat exchanger is to be used with a cross-flow air, the process then flows to block 525 where the fins with thermal isolation sections may be employed within the heat exchanger.

While the invention has been described in terms of several embodiments, those skilled in the art will recognize that the invention is not limited to the embodiments described, but can be practiced with modification and alteration within the spirit and scope of the appended claims. The description is thus to be regarded as illustrative instead of limiting.

What is claimed is:

1. A system, comprising:
an electronic component capable of generating heat;
a heat exchanger coupled to the electronic component, wherein the heat exchanger is to cool a liquid coolant transported through the heat exchanger by using at least one flow distribution path in a first direction; and
a fan coupled to the heat exchanger, wherein the fan is to provide an air flow in a second direction that generally counters the first direction.

2. The system of claim 1, wherein the heat exchanger includes an inlet, an outlet, and a flow distribution plate coupled to and positioned between the inlet and the outlet, the flow distribution plate including the flow distribution path transporting the liquid coolant from the inlet to the outlet.

3. The system of claim 1, wherein the heat exchanger is further coupled to a pump and is to include one or more fins, wherein at least one fin includes thermal isolation sections.

4. The system of claim 3, wherein the thermal isolation sections are separated by perforation or cuts.

5. A cooling apparatus, comprising:
a liquid coolant;
a pump to enhance flow of the liquid coolant in a closed loop;
a fan to provide an air flow; and
a heat exchanger coupled to the pump and to the fan, the heat exchanger including a flow distribution plate having at least one flow distribution path, the flow distribution path transporting the liquid coolant in a direction generally countering a direction of the air flow, the flow distribution plate coupled to one or more fins with at least one fin including thermal isolation sections.

6. The apparatus of claim 5, wherein the thermal isolation sections are separated from one another by a cut or perforation.

7. The apparatus of claim 5, wherein the thermal isolation sections are non-uniform.

8. The apparatus of claim 5, wherein when the flow distribution plate includes two or more flow distribution paths, the flow distribution paths are parallel channels.

9. The apparatus of claim 8, wherein the parallel channels are non-uniform.

10. The apparatus of claim 5, wherein when the flow distribution plate includes two or more flow distribution paths, the flow distribution paths are non-uniform and are to transport the liquid coolant in a direction generally countering the direction of the air flow.

11. A method, comprising:
using a heat exchanger to cool a heat-generating component, the heat exchanger coupled to a fan providing an air flow; and
causing a liquid coolant to flow through the heat exchanger in a direction generally opposite to a direction of the air flow.

12. The method of claim 11, wherein using the heat exchanger includes using fins to extract heat from the liquid coolant, wherein the fins are to have thermal isolation sections.

13. The method of claim 12, wherein the thermal isolation sections are separated by partial cuts or perforation.

14. The method of claim 11, wherein causing the liquid coolant to flow through the heat exchanger comprises:
coupling one or more flow distribution paths to an inlet and an outlet of the heat exchanger, and
allowing the liquid coolant to flow through the flow distribution paths.

15. The method of claim 14, wherein the one or more flow distribution paths are to be included in a flow distribution plate connecting the inlet to the outlet.

16. An apparatus, comprising:
a inlet and an outlet, the inlet to receive a liquid coolant and the outlet to release the liquid coolant;
a fan to provide an air flow in a first direction;
a flow distribution plate to connect the inlet to the outlet, the flow distribution plate to include one or more flow distribution paths to enable the liquid coolant to flow in a second direction generally countering the first direction; and
one or more fins, with at least one fin having multiple sections partially separated from one another.

17. The apparatus of claim 16, wherein the flow distribution paths are non-uniform.

18. The apparatus of claim 16, wherein the multiple sections are partially separated from one another by a cut or by perforation.

19. A cooling system, comprising:
a fan to provide an air flow; and
a heat exchanger coupled to the fan, the heat exchanger accommodating multiple passes of a flow path transporting a liquid coolant, the heat exchanger having one or more fins with at least one fin including thermal isolation sections, wherein each thermal isolation section is coupled with a pass of the flow path.

20. The system of claim 19, wherein the thermal isolation sections are partially separated from one another by a cut or by perforation.
